(19) United States
(12) Patent Application Publication
(10) Pub. No.: US 2023/0406709 A1
(43) Pub. Date: Dec. 21, 2023

(54) MODIFIED CARBON-BASED MATERIALS

(71) Applicant: YISSUM RESEARCH DEVELOPMENT COMPANY OF THE HEBREW UNIVERSITY OF JERUSALEM LTD, Jerusalem (IL)

(72) Inventor: Roie YERUSHALMI, Moshav Kfar Warburg (IL)

(21) Appl. No.: 18/251,427

(22) PCT Filed: Nov. 2, 2021
(86) PCT No.: PCT/IL2021/051299

§ 371 Date: May 2, 2023

Related U.S. Application Data
(60) Provisional application No. 63/108,574, filed on Nov. 2, 2020.

(51) Int. Cl. C01B 32/168; C23C 16/26; C23C 16/455

(52) U.S. Cl. CPC C01B 32/168; C23C 16/26; C23C 16/45527

(57) ABSTRACT

The invention concerns a composite material comprising a carbon-based material and a non-continuous film comprising a plurality of regions of a metal-based wetting material associated with the carbon-based material, the non-continuous film of the wetting material being configured to tune the carbon-based material to adhesively receive thereon a film of at least one polymeric material.

### TECHNOLOGICAL FIELD

The invention generally relates to carbon-based materials and methods for modifying their mechanical and chemical properties.

### BACKGROUND OF THE INVENTION

Nano-composite materials are multi-phase solid materials with one of their phases having at least one dimension in the nanometer range. Nano-composites encompass nanometer scale building blocks to form new materials with different and often improved physical and mechanical properties compared to the individual components. The mechanical and physical properties of nanocomposites are typically different from those of the constituent materials. Nanocomposite can include materials such as porous, colloids, gels and copolymers, with heterogeneous properties due to dissimilarities in structure and chemistry.

The reinforcing component in a composite material can be in the form of particles, sheets or fibers (e.g. CNT fibers). Due to the high aspect ratio and high surface to volume ratio of a reinforcing phase, nano-composites differ from conventional composite materials. Typically, the area of the interface between the reinforcement and a matrix phase is an order of magnitude larger than for conventional composite materials. Hence, a small portion of nanoscale reinforcement can induce large influence on the macro scale characteristic properties of the nanocomposite. For example, using CNTs as a reinforcing phase can dramatically improve the electrical and thermal conductivity of the composite.

The scope of CNT-based nanocomposites is quite wide with applications ranging from advanced batteries, super capacitors, light weight conductors, reinforced materials, antibacterial fabrics and more. However, despite extensive activity and major advances in the field performance of CNTs, and CNT-based composites falls short of any theoretical potential.

The establishment of procedures to develop carbon-based composite materials with superior performance requires improved methods for surface modification of macroscopic forms of CNT-based materials such as CNT mats, yarns, fibers, webs, carbon cloth, buckypaper, and others. Highly controlled surface modification and tailoring of surface relativities of such carbon materials is not straightforward, partly because of the tendency of CNTs to undergo spontaneous and ill-controlled aggregation and phase segregation during solution processing. Furthermore, most of the currently practiced methods for preparing nanocomposite carbon-based materials involve solution treatments for introducing the matrix components and for densification of the yarns which leads to limited control over the process and non-uniform composition of the nanocomposite. This leads to limited functionality.

A major advance in the preparation of CNT composite materials was demonstrated by the introduction of Layer-by-Layer (LBL) solution assembly of CNT/polyelectrolyte composites by addressing some of the key limitations in processing CNTs. Nevertheless, the currently available methodologies for processing CNT yarns are still quite limited.

Importantly, obtaining optimal functionality of high loading CNT-based nanocomposites, requires that the deposited matrix have a uniform, continuous, and maximal areal coverage over the CNT interfaces. Traditionally, covalent modification of the CNTs has commonly been considered to be important in order to obtain improved mechanical properties. However, at the same time, it is also known that defects, such as those introduced by covalent modification of the CNTs C-sp2 atoms, degrade both the mechanical properties and the electronic conductance of the composite.

Publication [1] discloses processes for forming carbon nanotubes composites involving vapor-phase chemistry. Specifically, the technology concerns vapor phase deposition of functionalities that are covalently bound to each other and which fully cover the surface of the nanotubes, so as to produce complete engulfment of the nanotube backbone.

### BACKGROUND PUBLICATIONS

[1] WO 2018/154572

### GENERAL DESCRIPTION

Coupling of polymers to carbon-based materials, amongst such materials CNT and CNT mats, requires surface treatment due to the incompatibility of the CNT surface with the polymeric overlayers. Modification of the CNT surface by introducing structural defects in the CNT structure results in degradation of the electronic properties of the CNTs which can affect the properties of a resulting composite. Thus, to avoid formation of such defects and overcome some of the other deficiencies inherent to carbon-based composites, another different approach for forming carbon-based composites is needed.

The inventor of the technology disclosed herein has developed a unique approach for tailoring surface properties of carbon-based materials such as CNTs and CNT mats by introducing non-covalently associated functional groups on the CNT surface, which allow retaining the CNT intrinsic structure and without causing surface defects. This approach was determined to increase compatibility of the carbon-based material with a great variety of polymeric resins, such as epoxy resins, to yield high quality composites.

By employing the technology disclosed herein, the characteristics of the carbon-based materials changed from hydrophobic to hydrophilic further resulting in a decrease in surface energy, which permitted better incorporation of the resin in the carbon-based material, as demonstrated from the FIB results and reflected in the mechanical properties discussed herein. A CNT-based composite produced by methods of the invention showed a different morphology as compared with a composite based on an untreated CNT. Stress-strain curves showed a different type of behavior which was indicative of the molecular details associated with vapor phase methods utilized to functionalize the CNT.

Composites of the invention are a novel class of materials which exhibits exceptional strengths and electrical conductivity which result from the uninterrupted covalent C—C sp2 bond network formed between individual carbon atoms in the CNTs. Functionalization of the CNT surface by means of vapor deposition, without inducing defects into the CNT structures, combined with effective solution or polymer melt layering of a polymeric resin on the CNT surface resulted in CNT-polymer nanocomposites which pave the way for a variety of applications.

Thus, in its broadest aspect, the invention concerns a composite material comprising a carbon-based material and a non-continuous film comprising a plurality of regions of a metal-based wetting material associated with the carbon-based material, the non-continuous film of the wetting material being configured to tune the carbon-based material to adhesively receive thereon a film of at least one polymeric material.

Also provided is a composite material comprising a carbon-based material having a non-continuous film comprising a plurality of regions of a metal-based wetting material associated with the carbon-based material, and a (continuous) film of at least one polymeric material, wherein the film being associated with the non-continuous film and with exposed regions of the carbon-based material

The invention also provides a composite material comprising a carbon-based material having (or associated with) a non-continuous film of a metal-based wetting material and a film of at least one polymeric material, wherein the film of the polymeric material is associated with the non-continuous film of the metal-based wetting material and with exposed regions of the carbon-based material.

Further provided is a composite in a form of a 3D object of a carbon-based material, the object being associated with a film of at least one polymeric material on at least a region of its surface, the film being associated with the 3D object via a plurality of regions of a metal-based wetting material selected to tune wettability of the carbon-based material, thereby permitting association of the polymeric material with both the carbon-based material forming the object and the plurality of regions of the metal-based wetting material.

Further still, the invention provides a composite material of at least one carbon-based material and a polymer, the composite being prepared by:
(i) Vapor deposition of a non-continuous film of a metal-based recipient material; and
(ii) Wet (solution) or melt deposition of a polymer film (via deposition of the polymer or of a polymerizable polymer precursor).

As used herein, the term “composite material” refers to a product of the invention that is constructed of at least three regions or layers or films or coats that are layered or stacked to provide the composite. The three regions, two of which typically shaped as layers or films or material regions, are the carbon-based material (which may be of any shape and may have differing contours), the non-continuous film formed from the wetting material, herein referred to as a “wetting film” or a “recipient layer”, and the film formed of the polymeric material, herein referred to as a “polymeric film”. The interaction or association between the material regions is non-covalent, as further disclosed herein. The three regions are essentially inseparable, namely the polymer film is not peelable from the recipient film.

As disclosed herein, the term “film”, being exchangeable with “layer” or “coat” stands to mean a spread of a material having a very low dimension with respect to its thickness, wherein the film substantially overlays or covers the underlining material region. The wetting film is a non-continuous film which comprises a plurality of spaced-apart randomly shaped and sized islands or regions or anchoring regions of the at least one metal-based wetting material. Regions not covered by the wetting material are exposed regions of the carbon-based materials. Unlike the non-continuous film of the wetting material, the polymeric film is substantially continuous, namely it substantially covers the surface of the carbon-based material and is associated with both the spaced-apart regions of the wetting materials and the exposed regions of the carbon-based material. Both films substantially follow the outermost surface and contour of the carbon-based material, e.g., a CNT.

Unlike the wetting film, the polymeric film is substantially continuous; namely it is not structured as spaced-apart regions of the polymer. It extends both the surface of the wetting film islands and the exposed regions therebetween. Yet the polymeric film may be porous or permeable.

The density of the spaced-apart regions of the wetting material or the degree of material continuity may be tailored by selection of the vapor phase deposition conditions and the layer thickness selected. As discussed herein, vapor deposition permits tuning of the degree of wetting of the carbon-based material. In turn, the density of the plurality of regions of the metal-based wetting material may influence the ability to tune the wettability of the carbon-based material. It is evident that having a fully wetted surface does not permit strong adhesivity or anchoring of the polymeric material to form a stable and mechanically strong composite. It is thus required that spaced-apart material regions are formed, leaving exposed certain regions of the carbon-based material, thereby permitting association of the polymeric material with both the carbon-based material and the metal-based wetting material, to yield a film of the polymeric material that engulfs the carbon-based material. This configuration renders, for example, excellent and superior properties, such as electrical properties stemming from the direct interaction between the polymer film, which may be of a conductive nature and the conductive CNT or carbon fiber, without interference from the wetting layer.

Typically, the carbon-based material is coated with a film of the polymeric material, which film being in some embodiments continuous. For some applications, however, the polymeric film may be configured to cover only certain areas or regions of the carbon-based material. These regions may be spaced-apart regions on the surface of the carbon-based materials or a single continuous region which does not cover the full surface of the material. In some embodiments, the spaced-apart regions or the region of the carbon-based material that is covered with the material films, as disclosed, are patterned; in other words, the films are provided as shaped material regions, wherein said shaped regions may be produced by any shaping tool or technique known in the art.

Typically, each of the films has a thickness in the nanometer or micrometer regime. In some embodiments, the thickness of the wetting film spaced-apart regions is between 1 and 100 nm. In some embodiments, the thickness is between 2 and 90, 2 and 80, 2 and 70, 2 and 60, 2 and 50, 2 and 40, 2 and 30, 2 and 20 or 2 and 10 nm. In other embodiments, the thickness is between 1 and 10, 1 and 9, 1 and 8, 1 and 7, 1 and 6, 1 and 5, 1 and 4 or between 1 and 3 nm.

The thickness of the polymeric film may range from several nanometers, several micrometers or bulk, namely several millimeters. Thus, the thickness of both the wetting film and the polymeric film may range from several nanometers, say 10 nm, to several millimeters, say 5 mm.

For certain applications, as further disclosed herein, the composite of the invention may include additional films or layers of various other materials that are formed on the polymeric film. However, in all composites of the invention, the wetting film is formed directly on the carbon-based material and the polymeric film is formed directly on the wetting film, such that the polymeric material can associate with the wetting material and the carbon-based material. No intermediate layers or films are provided between the carbon-based material and the wetting film or between the wetting film and the polymeric film.

As used herein, the term “wetting” or any lingual variation of the term refers to the ability to render the polymeric material capable of maintaining contact with the carbon-based material. In terms of the technology disclosed herein, the term refers to rendering the carbon-based material associable with the polymeric film through voids or gaps or exposed regions located between islands of the wetting material. It is highly surprising that the spaced-apart regions of the metal-based wetting material, not providing a full or complete wetting film on the carbon-based material, are sufficient to decrease the surface energy of the carbon-based material to a degree enabling attractive, non-repulsive, association between the carbon-based material and the polymeric film with the wetting regions acting as adherent regions by which secured association is rendered possible.

While the technology disclosed herein may be applicable to other various substrate materials, carbon-based materials are unique and present an intriguing functional class of materials. The “carbon-based material” is thus any carbonaceous particulate or structured material which association with a polymer is desired. Typically, the carbon-based material is a carbon allotrope, or a material which substantially includes only carbon atoms. Such materials may be sp2 systems, but not necessarily so. Non-limiting examples of carbon-based materials include graphite, carbon fibers, carbon black powder, amorphous carbon powder, carbon nanofoam, glassy carbon, graphene and graphene flakes, graphene oxide, reduced graphene oxide, carbon nanofibers, carbon nanotubes (CNTs), fullerenes (buckyballs), diamond powder, diamond nanoparticles, diamond coating, and others. Each of the aforementioned materials constitutes an embodiment of the invention.

Additionally, the carbon-based material may be a carbon macrostructure composed of carbon-based materials as defined herein.

In some embodiments, the carbon based material is graphene or a graphene-based structure, such as graphene flakes, graphene nanosheets, graphene nanoribbons, and graphene nanoparticles.

Among the carbon allotropes, CNT has become a center of attraction in the field of nanomaterials due to its unique structure and properties. Nanotubes are nearly one-dimensional structures due to their high length to diameter ratio. They exhibit a unique combination of electronic, thermal, mechanical, and chemical properties, which promise a wide range of potential applications in key industrial applications. Generally speaking, the CNT encompasses any one or combination of carbon allotropes of the fullerene family selected from single walled carbon nanotubes (SWCNTs), double-walled carbon nanotubes (DWCNTs) and multi-walled carbon nanotubes (MWCNTs). The CNT may have between 1 to 10 walls and have varying dimensions.

Where composites of the invention are based on CNT, the CNT may be provided as a single molecular structure that is coated with a wetting film and a polymeric film, as disclosed herein, yielding individual nanotube composite structures; or in a form of a collection of CNTs or as CNT assemblies. The “CNT assembly” is a collection or a bundle of two or more CNTs, shaped as a fiber that self-assembles into fiber bundles or a web in a random or an organized fashion. The organized form may take the shape of a CNT web or a CNT bundle. Within the assembly the CNTs may be branched, crosslinked, or share common walls with one another. They may have any defined shape, positioning, orientation and density. The assemblies may be formed as a collection of such CNT assemblies into macrostructures in which the CNT bundles or assemblies are distributed, optionally uniformly, to provide a material continuity which comprises mainly or substantially (or consists of) a plurality of CNT assemblies. The CNT assemblies comprised within the macrostructure may be associated via their surface layers. For example, they may be associated by any one or combination of hydrogen bonds (donor and acceptor), crosslinking and pi-interaction. In some embodiments, the macrostructure is selected from a CNT web, a CNT woven mat, a CNT non-woven mat, a CNT sheet, a CNT paper, a hydrogel, a bundle of assemblies, a buckypaper, and a carbon fiber.

In some embodiments, the carbon-based material is CNT, e.g., provided as a CNT powder, or is CNT-based. In some embodiments, the carbon-based material is a CNT macrostructure, such as a CNT mat, a CNT sheet, or a CNT paper.

In some embodiments, CNT is in a form selected from a CNT mat, a CNT woven mat, a CNT non-woven mat, a CNT sheet, a CNT paper and a CNT hydrogel.

All of the carbon-based materials disclosed herein are known in the art and are commercially available. Methods of preparation of the carbon-based materials are known in the art and may be used to produce such materials.

In most general terms, composites of the invention are formed by modifying the surface energy of the carbon-based material. This is achievable by vapor phase deposition technique such as atomic layer deposition (ALD), molecular atomic layer deposition (MALD), as well as various tandem techniques to deposit, enabling deposition of thin material regions of the wetting material. By employing vapor phase deposition methods, the material deposited does not undergo covalent association with atoms in the carbon-based materials, does not induce defects in the carbon-based materials and therefore does not diminish, in any way, properties associated with the carbon-based material, e.g., conductivity and allows control on the size and density of the wetting material regions formed.

The vapor phase deposition allows controlled, layer-by-layer deposition of thin material regions by dosing of gas phase chemical precursors. As known in the art, in a typical ALD process a substrate, being the carbon-based material, is exposed to precursor vapors avoiding full surface coverage. Next, the reaction chamber is purged with an inert gas to remove any physiosorbed excess of precursors and to avoid direct gas-phase reaction between the precursors. This is followed by dosing of a second precursor and purge. Repeating the sequence of steps results in sequential films deposition with atomic or molecular layer increment per complete cycle. Film growth relies on a self-limiting surface saturated reaction at each of the steps.

Molecular Layer Deposition (MLD) is another vapor phase deposition technique that resembles the ALD. However, where ALD is limited exclusively to inorganic coatings, the precursor chemistry in MLD is expanded to include organics and enables linking both types of building blocks together in a controlled way to build up organic-inorganic hybrid materials.

Thus, according to aspects of the invention, a carbon-based material is treated under conditions of vapor phase deposition to form a plurality of random metal-based recipient regions (or a non-continuous film thereof) that wets the surface of the carbon-based material, allowing strong interaction with the polymeric material. The “metal-based wetting material” is thus a metallic material, i.e., a material comprising at least one metal atom in an ionic or complex form, having functionalities which enable physical or chemical association with a layer of a polymeric material that is subsequently applied thereon. The wetting material that is used reduces surface tension of the polymeric resin to allow it to spread onto the carbon-based material surface. Lowering the surface tension lowers the energy required to spread the polymeric film, thus weakening the cohesive properties of the polymer and strengthening its adhesive properties; thus, rendering the carbon-based material capable for “adhesively receive thereon a film of at least one polymeric material”, as used herein. Putting it differently, the metal-based wetting agent may be regarded as an adhesive material providing a plurality of anchoring localities (or regions), which dramatically reduce the surface energy and allowing a strong and substantially irreversible interaction with the polymeric material.

As the adhesivity is substantially not reversible, the polymeric film is not peelable from the surface of the carbon-based material.

The wetting material is not any of the traditional surfactants used to increase wettability of surfaces. In fact, such are not within the scope of the present invention as they provide a wettability that at times influences the degree of adhesivity of the polymeric film and thus the strength of association. Thus, in some embodiments, the non-continuous film of the wetting material is free of surfactants.

The metal-based wetting material may be an inorganic material, organic material or a hybrid material comprising or a material associating to one or more metal atoms. In some embodiments, the metal-based wetting material comprises a plurality of metal atoms in-layer associated to each other, directly or via bridging atoms or organic ligands, wherein the metal atoms are further associated with one or more surface exposed functionalities which are selected to render possible an association of at least one additional material (e.g., material film such as a polymeric material film) to the wetting film. Such functionalities may be hydroxide functionalities, oxide functionalities, alkoxide functionalities, amine functionalities, benzyl functionalities, and others. The one or more metal atoms present may be selected from Al, W, Sc, Ti, V, Cr, Mn, Fe, Co, Ni, Cu, Zn, Y, Zr, Nb, Mo, Tc, Ru, Rh, Re, Pd, Ag, Au, Cd, In, Sn, Sb, Te, Hg, Tl, Pb, Pt, Bi and Po. In some embodiments, the metal atom is Zn, Zr, Fe, Ti, V, Cu, Ni, Bi or W; or is Al, Ti, Zn, Fe, V, Ni, Cu or Cr; or is Ti, Al or Zn.

In some embodiments, the metal atom is provided in a metal complex or as a metal ion, or a metal oxide, or in a form associated with an inorganic or an organic ligand or functionality or counterion.

Such may be metalcone materials; metal-based complexes of at least one organic material; and others.

Non-limiting examples of metal-based wetting materials include NO₂-trimethylaluminum (NO₂-TMA); metalcones such as alucones, zincones, titanicones, vanadicones, zircones, hafnicones, mangancones; metal quinolones; metal-alcohol complexes such as metal complexes of ethylene glycol, propylene glycol, propylene triol, glycerol, threitol, xylitol and sorbitol; amine alcohols (comprising both amine and alcohol functionalities, e.g., ethanol amine); metal-amine complexes such as metal complexes of NH₂, NHMe, NMe₂, NHEt, NEt₂; bi- or multi-functional molecules capable of reacting with the metal precursor via two or more functionalities; metal oxides; and hybrid materials.

As known in the art, a “metalcone” is a metal complex of the form R—X-M-X—R (alkoxide), wherein the metal M is connected through a heteroatom X, which may be an oxygen atom (—O—), a nitrogen atom (—N—) or a sulfur atom (—S—) to an organic moiety (R). Where the heteroatom X is oxygen, examples of metalcones are titanium-ethylene glycol and aluminum-ethylene glycol, wherein the Ti and Al are the metal atoms, the oxygen atom of the ethylene glycol constitutes the point of connectivity with the metal, and the ethylene glycol is the organic moiety. Any organic moiety R may be utilized, with a variety of metals, generating metacones of zinc (zincone), aluminum (alucone), titanium (titanicone), etc. The number of M-O (alkoxide) bonds may vary depending on the metal.

In some embodiments, the metalcone may have the structure R—N-M, wherein M is the metal, the heteroatom linking the organic moiety to the metal is a nitrogen atom (—N—), and R is the organic residue. Such materials include diamines e.g., ethylene diamine and alcohol-amines e.g., ethanolamine. As with the oxygen cases, any organic moiety R may be utilized, with a variety of metals, generating metacones of zinc (zincone), aluminum (alucone), titanium (titanicone), etc. The number of M-N (alkoxide) bonds may vary depending on the metal.

Formation of metal-based wetting films as utilized herein are known in the art, for example in US application no. 2010/0320437, US application no. 2020/0087148, U.S. Pat. No. 9,587,117,

The wetting film is a non-continuous recipient film onto which a polymeric material is applied. As such the wetting film need not be of any specific thickness, provided that the region of the carbon-based material to be functionalized is not fully covered or fully wetted.

The associations between the films formed on the carbon-based material, namely between the carbon-based material surface and the metal-based wetting film, is physical or is non-covalent in nature. In other words, the associations between the wetting film and the carbon-based material does not involve sharing of electron pairs (non-covalent). The association between the wetting film and the polymeric film may be partially covalent, however, the nature of the association may be dependent on the materials used.

Thus, the associations may be mainly physical in nature, or involve electrostatic interactions such as ionic interaction, hydrogen bonding, π-π interactions or other π-stacking interactions, dipole-dipole interactions and/or van der Waals force-mediated interactions, more than covalent interactions.

Excluded from aspects and embodiments of the invention are carbon-based materials that are linked or associated with a polymeric material via pendent association, whereby a polymer is pendent or flanked from the carbon-based material. For examples, excluded are such structures wherein a carbon-based material, e.g., CNT, is associated through one or more of its carbon atoms with one or more polymer structures. Also excluded are such carbon-based materials that are wrapped by polymer fibers or structures, wherein the wrapping is reversible.

In some embodiments, the carbon-based material is or comprises CNT and the non-continuous wetting film is or comprises a metalcone.

In some embodiments, the carbon-based material comprises CNT and the non-continuous wetting film comprises a metalcone.

In some embodiments, the carbon-based material comprising CNT is a CNT mat and the non-continuous wetting film is a metalcone.

In some embodiments, the metalcone is selected form alumicones and titanicones

The polymeric film may be of any polymeric material. The polymeric material may be selected to endow the final composite with a functionality or a property that enhances or adds or improves on any attribute of the carbon-based material or may be selected to provide a composite of a particular constitution. The polymeric material may thus be selected amongst any of the polymeric materials known in the art. In some embodiments, the polymeric material is selected amongst thermoplastics, thermosets, and elastomers polymers.

In some embodiment, the polymer is selected amongst thermoplastic polymers. These include, without limitation, acrylics, acrylonitrile butadiene styrene (ABS), polylactic acid (PLA), polybenzimidazole, polycarbonates, polyether sulfones, polyoxymethylenes, polyether ether ketone, polyetherimides, polyethylene, polyphenylene oxide, polyphenylene sulfide, polypropylene, polystyrene, polyvinyl chloride, polyvinylidene fluoride, and others.

In some embodiments, the polymer is selected amongst thermoset polymers. Non-limiting examples of thermoset polymers include phthalonitrile, polyesters, polyurethanes, diallyl-phthalate (DAP), polyepoxides, polyimideses, polycyanurates, furans, silicones, vinyl esters and others.

In some embodiments, the polymer is an elastomer. The elastomer may be selected amongst a great variety of rubbers, identified based on their degree of saturation or unsaturation. Non-limiting examples include polyisoprenes, polybutadienes, chloroprenes, styrene-butadienes, epichlorohydrins, polyacrylics, ethylene-vinyl acetate, polysulfides and others.

In some embodiments, the polymer is a conductive polymer. Non-limiting examples of conductive polymers include polyfluorenes, polyphenylenes, polypyrenes, polyazulenes, polynaphthalenes, polyfurans, polythiophenes, polyanilines, polypyrroles, polycarbazoles, polyindoles, polyazepines, polyanilines, polythiophenes, poly(3,4-ethylenedioxythiophene)s, poly(p-phenylene sulfide), polyacetylenes, poly(p-phenylene vinylene), and others.

In some embodiments, the polymer is an elastomer or a thermoset polymer.

In some embodiments, the polymer is derived from a prepolymer or a polymer resin. In some embodiments, the polymer is derived from a resin selected from polyester resins, epoxy resins, furan resins, silicone resins, vinyl ester resins, and others.

In some embodiments, the polymer is a polyepoxide or is derived from an epoxy resin. In some embodiments, the epoxy material or resin is provided as a mixture at least one material having an epoxide moiety (for example bi-functional phenol-epoxide) and at least one hardener, such as a diamine which is the cross-linker. Examples of commercially available epoxy combinations include Araldite LY 5052/Aradur 5052 system, composed of the epoxy resin phenol novolac (EPN) and isophorone diamine (IPDA) as the hardener.

As mentioned below, in some embodiments, the epoxy material or resin is provided separately from the hardener but are used in combination to achieve film curing.

In some embodiments, the polymer is derived from phthalonitrile.

Where resins or prepolymers are concerned, to achieve a cured polymeric film, the polymer film may be formed by applying the polymer in a flowable form, or by applying a resin thereof or a prepolymer form thereof directly on the surface of the recipient film under conditions that allow polymer curing. Such conditions may involve the use of a crosslinking agent or a hardener that is configured to induce crosslinking of the resin or prepolymer, as further disclosed below.

In another of its aspects, the invention concerns a composite material comprising a CNT mat having a non-continuous film comprising a plurality of regions of a metal-based wetting material associated with the carbon-based material, the non-continuous film of the wetting material being configured to tune the carbon-based material to adhesively receive thereon a film of an epoxy material.

Also provided is a composite comprising a carbon-based material being or comprising CNT coated with a non-continuous wetting film of a metal-based wetting material, the non-continuous wetting film being associated with a film of an epoxy material (polyepoxide). In some embodiments, the CNT is CNT mat.

The invention also provides a composite material comprising a CNT mat having a plurality of wetting regions associating a film of epoxy (polyepoxide). In some embodiments, the wetting material is a metalcone.

Further provided is a CNT mat having an epoxy film on at least a region of its surface, the film being associated with the CNT mat via a plurality of wetting regions of a metal-based wetting material that is non-covalently associated with the CNTs in said mat.

Further still, the invention provides a process for manufacturing a composite material of at least one carbon-based material and a polymer, the process comprising:
(iii) Vapor deposition of a non-continuous metal-based recipient film; and
(iv) Wet or melt deposition of a polymer or a polymerizable polymer precursor.

The non-continuous wetting film or metal-based recipient film, provided directly on the carbon-based material, e.g., CNT mat, is formed by vapor phase deposition. The vapor phase deposition may be one or a combination of atomic layer deposition (ALD), molecular layer deposition (MLD), combined ALD/MLD, spatial ALD, and tandem catalyst ALD/MLD. As mentioned hereinabove, ALD and MLD are vapor phase chemical techniques, which can be used separately or in combination, allowing thin-film deposition via consecutive and self-limiting surface reactions. ALD allows inorganic film depositions and MLD allows organic film depositions. Spatial ALD (S-ALD) involves layer-by-layer film deposition in which reactive precursors are separated in space rather than in time, as with conventional ALD. In tandem catalyst ALD/MLD, each sub-cycle catalyzes the deposition of the complementary sub-cycle.

The ALD/MLD conditions may vary in accordance with processing parameters known in the art. The materials that may be deposited in accordance with ALD or MLD and the conditions that can be used may be adapted from the general state of the art. See for example Meng X., J. Mater. Chem. A, 2017, 5, 18326; Leskela M., Thin Solid Films, 2002, 409, 138; and Van Bui H., Chem. Commun., 2017, 53, 45. The content of any of these publications, vis-à-vis ALD/MLD conditions and materials is incorporated herein by reference.

In some embodiments, the ALD step is carried out in an ALD reactor, and the process comprises introducing into the ALD reactor at least one metal precursor composition under conditions permitting direct vaporization, bubbling or sublimation into contact with the carbon-based material.

In some embodiments, the ALD/MLD reactor is selected from conventional ALD reactor, fluidized bed rector, high pressure spatial ALD reactor or any other type of reactor.

The at least one metal source or precursor is a metal salt or metal complex of any metallic element of the Periodic Table of the Elements. In some embodiments, the metal source is of a transition metal or a metalloid. In some embodiments, the metal source is of a metal selected from Al, W, Sc, Ti, V, Cr, Mn, Fe, Co, Ni, Cu, Zn, Y, Zr, Nb, Mo, Tc, Ru, Rh, Re, Pd, Ag, Au, Cd, In, Sn, Sb, Te, Hg, Tl, Pb, Pt, Bi and Po. In some embodiments, the metal source is of a metal selected from Zn, Zr, Fe, Ti, V, Cu, Ni, Bi and W. In other embodiments, the metal is selected from Al, Ti, Zn, Fe, V, Ni, Cu and Cr. In other embodiments, the metal is Ti, Al or Zn.

The metal salt or metal complex may be selected from the following, wherein “M” represents a metal atom, as disclosed herein:
chlorides, e.g., selected from MCl, MCl₂, MCl₃, MCl₄, MCl₅, and MCl₆;
chlorides hydrates, e.g., selected from MCl·xH₂O, MCl₂·xH₂O, MCl₃·xH₂O, MCl₄·xH₂O, MCl₅·xH₂O, and MCl₆·xH₂O, wherein x varies based on the nature of M;
hypochlorites/chlorites/chlorates/cerchlorates (abbreviated ClOₙ⁻, n=1, 2, 3, 4), e.g., selected from MClOₙ, M(ClOₙ)₂, M(ClOₙ)₃, M(ClOₙ)₄, M(ClOₙ)₅, and M(ClOₙ)₆;
hypochlorites/chlorites/chlorates/perchlorates hydrates, e.g., selected from MClOₙ·xH₂O, M(ClOₙ)₂·xH₂O, M(ClOₙ)₃·xH₂O, M(ClOₙ)₄·xH₂O, M(ClOₙ)₅·xH₂O, and M(ClOₙ)₆·xH₂O, wherein x varies based on the nature of M, and n=1, 2, 3, 4;
carbonates, e.g., selected from M₂CO₃, MCO₃, M₂(CO₃)₃, M(CO₃)₂, M₂(CO₃)₂, M(CO₃)₃, M₃(CO₃)₄, M(CO₃)₅, M₂(CO₃)₇;
carbonate hydrates, e.g., selected from M₂CO₃·xH₂O, MCO₃·xH₂O, M₂(CO₃)₃·xH₂O, M(CO₃)₂·xH₂O, M₂(CO₃)₂·xH₂O, M(CO₃)₃·xH₂O, M₃(CO₃)₄·xH₂O, M(CO₃)₅·xH₂O, and M₂(CO₃)₇·xH₂O, wherein x varies based on the nature of M;
carboxylates (abbreviated RCO₂⁻, and including acetates), e.g., selected from MRCO₂, M(RCO₂)₂, M(RCO₂)₃, M(RCO₂)₄, M(RCO₂)₅, and M(RCO₂)₆;
carboxylates hydrates (abbreviated RCO₂⁻), e.g., selected from MRCO₂·xH₂O, M(RCO₂)₂·xH₂O, M(RCO₂)₃·xH₂O, M(RCO₂)₄·xH₂O, M(RCO₂)₅·xH₂O, and M(RCO₂)₆·xH₂O, wherein x varies based on the nature of M;
carboxylate (the group RCOO⁻, R is aliphatic chain, which may be saturated or unsaturated), e.g., selected from CH₃CH═CHCOOM (metal crotonate), CH₃(CH₂)₃CH═CH(CH₂)₇COOM (metal myristoleate), CH₃(CH₂)₅CH═CH(CH₂)₇COOM (metal palmitoleate), CH₃(CH₂)₈CH═CH(CH₂)₄COOM (metal sapienate), CH₃(CH₂)₇CH═CH(CH₂)₇COOM (metal oleate), CH₃(CH₂)₇CH═CH(CH₂)₇COOM (metal elaidate), CH₃(CH₂)₅CH═CH(CH₂)₉COOM (metal vaccinate), CH₃(CH₂)₇CH═CH(CH₂)₁₁COOM (metal erucate), C₁₇H₃₅COOM (metal stearate);
oxides, e.g., selected from M₂O, MO, M₂O₃, MO₂, M₂O₂, MO₃, M₃O₄, MO₅, and M₂O₇;
acetates, e.g., (the group CH₃COO⁻, abbreviated AcO⁻) selected from AcOM, AcO₂M, AcO₃M, and AcO₄M;
acetates hydrates, (the group CH₃COO⁻, abbreviated AcO⁻), e.g., selected from AcOM·xH₂O, AcO₂M·xH₂O, AcO₃M·xH₂O, and AcO₄M·xH₂O, wherein x varies based on the nature of M;
acetylacetonates (the group C₂H₇CO₂⁻, abbreviated AcAc⁻), e.g., selected from AcAcM, AcAc₂M, AcAc₃M, and AcAc₄M;
acetylacetonate hydrates (the group C₂H₇CO₂⁻, abbreviated AcAc⁻), e.g., selected from AcAcM·xH₂O, AcAc₂M·xH₂O, AcAc₃M·xH₂O, and AcAc₄M·xH₂O, wherein x varies based on the nature of M;
nitrates, e.g., selected from MNO₃, M(NO₃)₂, M(NO₃)₃, M(NO₃)₄, M(NO₃)₅, and M(NO₃)₆;
nitrates hydrates, e.g., selected from MNO₃·xH₂O, M(NO₃)₂·xH₂O, M(NO₃)₃·xH₂O, M(NO₃)₄·xH₂O, M(NO₃)₅·xH₂O, and M(NO₃)₆·xH₂O, wherein x varies based on the nature of M;
nitrites, e.g., selected from MNO₂, M(NO₂)₂, M(NO₂)₃, M(NO₂)₄, M(NO₂)₅, and M(NO₂)₆;
nitrites hydrates, e.g., selected from MNO₂·xH₂O, M(NO₂)₂·xH₂O, M(NO₂)₃·xH₂O, M(NO₂)₄·xH₂O, M(NO₂)₅·xH₂O, and M(NO₂)₆·xH₂O, wherein x varies based on the nature of M;
cyanates, e.g., selected from MCN, M(CN)₂, M(CN)₃, M(CN)₄, M(CN)₅, M(CN)₆;
cyanates hydrates, e.g., selected from MCN·xH₂O, M(CN)₂·xH₂O, M(CN)₃·xH₂O, M(CN)₄·xH₂O, M(CN)₅·xH₂O, and M(CN)₆·xH₂O, wherein x varies based on the nature of M;
sulfides, e.g., selected from M₂S, MS, M₂S₃, MS₂, M₂S₂, MS₃, M₃S₄, MS₅, and M₂S₇;
sulfides hydrates, e.g., selected from M₂S·xH₂O, MS·xH₂O, M₂S₃·xH₂O, MS₂·xH₂O, M₂S₂·xH₂O, MS₃·xH₂O, M₃S₄·xH₂O, MS₅·xH₂O, and M₂S₇·xH₂O, wherein x varies based on the nature of M;
sulfites, e.g., selected from M₂SO₃, MSO₃, M₂(SO₃)₃, M(SO₃)₂, M₂(SO₃)₂, M(SO₃)₃, M₃(SO₃)₄, M(SO₃)₅, and M₂(SO₃)₇;
sulfites hydrates selected from M₂SO₃·xH₂O, MSO₃·xH₂O, M₂(SO₃)₃·xH₂O, M(SO₃)₂·xH₂O, M₂(SO₃)₂·xH₂O, M(SO₃)₃·xH₂O, M₃(SO₃)₄·xH₂O, M(SO₃)₅·xH₂O, and M₂(SO₃)₇·xH₂O, wherein x varies based on the nature of M;
hyposulfite, e.g., selected from M₂SO₂, MSO₂, M₂(SO₂)₃, M(SO₂)₂, M₂(SO₂)₂, M(SO₂)₃, M₃(SO₂)₄, M(SO₂)₅, and M₂(SO₂)₇;
hyposulfite hydrates, e.g., selected from M₂SO₂·xH₂O, MSO₂·xH₂O,
M₂(SO₂)₃·xH₂O, M(SO₂)₂·xH₂O, M₂(SO₂)₂·xH₂O, M(SO₂)₃·xH₂O, M₃(SO₂)₄·xH₂O, M(SO₂)s·xH₂O, and M₂(SO₂)₇·xH₂O, wherein x varies based on the nature of M;
sulfate, e.g., selected from M₂SO₃, MSO₃, M₂(SO₃)₃, M(SO₃)₂, M₂(SO₃)₂, M(SO₃)₃, M₃(SO₃)₄, M(SO₃)₅, and M₂(SO₃)₇;
sulfate hydrates, e.g., selected from M₂SO₃·xH₂O, MSO₃·xH₂O, M₂(SO₃)₃·xH₂O, M(SO₃)₂·xH₂O, M₂(SO₃)₂·xH₂O, M(SO₃)₃·xH₂O, M₃(SO₃)₄·xH₂O, M(SO₃)₅·xH₂O, and M₂(SO₃)₇·xH₂O, wherein x varies based on the nature of M;
thiosulfate, e.g., selected from M₂S₂O₃, MS₂O₃, M₂(S₂O₃)₃, M(S₂O₃)₂, M₂(S₂O₃)₂, M(S₂O₃)₃, M₃(S₂O₃)₄, M(S₂O₃)₅, and M₂(S₂O₃)₇;
thioulfate hydrates, e.g., selected from M₂S₂O₃·xH₂O, MS₂O₃·xH₂O, M₂(S₂O₃)₃·xH₂O, M(S₂O₃)₂·xH₂O, M₂(S₂O₃)₂·xH₂O, M(S₂O₃)₃·xH₂O, M₃(S₂O₃)₄·xH₂O, M(S₂O₃)₅·xH₂O, and M₂(S₂O₃)₇·xH₂O, wherein x varies based on the nature of M;
dithionites, e.g., selected from M₂S₂O₄, MS₂O₄, M₂(S₂O₄)₃, M(S₂O₄)₂, M₂(S₂O₄)₂, M(S₂O₄)₃, M₃(S₂O₄)₄, M(S₂O₄)₅, and M₂(S₂O₄)₇;
dithionites hydrates, e.g., selected from M₂S₂O₄·xH₂O, MS₂O₄·xH₂O, M₂(S₂O₄)₃·xH₂O, M(S₂O₄)₂·xH₂O, M₂(S₂O₄)₂·xH₂O, M(S₂O₄)₃·xH₂O, M₃(S₂O₄)₄·xH₂O, M(S₂O₄)₅·xH₂O, and M₂(S₂O₄)₇·xH₂O, wherein x varies based on the nature of M;
phosphates, e.g., selected from M₃PO₄, M₃(PO₄)₂, MPO₄, and M₄(PO₄)₃;
phosphates hydrates, e.g., selected from M₃PO₄·xH₂O, M₃(PO₄)₂·xH₂O, MPO₄·xH₂O, and M₄(PO₄)₃·xH₂O, wherein x varies based on the nature of M;
Metal alkyls;
Metal alkoxides;
Metal amines;
Metal phosphines;
Metal thiolates;
Combined cation-anion single source precursors, i.e., molecules that include both cation and anion atoms, for example of the formula M(E₂CNR₂)₂ (M is a metal, E is for example a chalcogenide, and R is alkyl, amine alkyl, silyl alkyl, phosphoryl alkyl, phosphyl alkyl).

In some embodiments, the metal salt or metal complex may be selected from:
a metal halide, as disclosed herein, wherein the halide is CI, Br, I or F;
a metal alkoxide;
a metal alkyl, wherein the alkyl ligand may be a long alkyl group (comprising more than 5 carbon atoms, including aryl groups), or a short alkyl group (comprising between 1 and 5 carbon atoms), wherein the alkyl is optionally substituted with one or more alcohol or amine groups;
a metal acetylacetonate; and
a metal complex with one or more ligand moieties.

In some embodiments, the metal source or precursor is selected from aluminum acetylacetonate, aluminum s-butoxide, aluminum ethoxide, aluminum hexafluoro acetylacetonate, aluminum i-propoxide, dimethylaluminum i-propoxide, tri-i-butylaluminum, triethylaluminum, triethyl(tri-sec-butoxy)dialuminum, tris(2,2,6,6-tetramethyl-3,5-heptanedionato)aluminum, triphenyl bismuth, tris(2,2,6,6-tetramethyl-3,5-heptanedionato)bismuth(III), dimethylcadmium, bis(cyclopentadienyl)chromium, bis(ethylbenzene)chromium, bis(pentamethylcyclo pentadienyl)chromium, bis(i-propylcyclopentadienyl)chromium, chromium(III) acetylacetonate, chromium carbonyl, chromium(III) hexafluoroacetylacetonate, tris (2,2,6,6-tetramethyl-3,5-heptane dionato)chromium(III), bis(cyclopentadienyl)cobalt(II), bis(N,N′-di-i-propylacetamidi nato)cobalt(II), cobalt tricarbonyl nitrosyl, tris(2,2,6,6-tetramethyl-3,5-heptane dionato)cobalt(III), bis(2,2,6,6-tetramethyl-3,5-heptanedionato) copper(II), copper(II) hexafluoroacetylacetonate, copper(II) hexafluoroacetylacetonate, copper(II) hexafluoro acetylacetonate, copper(II) trifluoroacetylacetonate, dimethyl (acetylacetonate)gold(III), dimethyl(trifluoroacetylacetonate)gold(III), indium(III) trifluoroacetylacetonate, trimethylindium, tris(2,2,6,6-tetramethyl-3,5-heptanedionato) indium(III), bis(cyclo pentadienyl)iron, bis(N,N′-di-t-butyl acetamidinato)iron(II), bis(ethylcyclo pentadienyl) iron, bis(pentamethylcyclopenta dienyl)iron, bis(i-propylcyclopenta dienyl)iron, cyclohexadiene iron tricarbonyl, iron pentacarbonyl, iron pentacarbonyl, iron(III) trifluoroacetylacetonate, tris(2,2,6,6-tetramethyl-3,5-heptanedionato)iron(III), bis(2,2,6,6-tetramethyl-3,5-heptanedionato)lead(II), bis(ethylcyclopentadienyl) manganese, bis(ethylcyclopentadienyl)manganese, bis(penta methylcyclopentadienyl) manganese, manganese carbonyl, tris(2,2,6,6-tetramethyl-3,5-heptanedionato) manganese(III), bis(ethylbenzene)molybdenum, cycloheptatriene molybdenum tricarbonyl, molybdenum carbonyl, bis(cyclopentadienyl)nickel, bis(ethylcyclo pentadienyl)nickel, bis(pentamethyl cyclopentadienyl)nickel, bis(i-propylcyclopenta dienyl)nickel, bis(2,2,6,6-tetramethyl-3,5-heptanedionato)nickel(II), nickel(II) acetylacetonate, nickel(II) acetylacetonate, nickel carbonyl, bis(2,2,6,6-tetramethyl-3,5-heptanedionato)palladium(II), platinum(II) hexafluoroacetylacetonate, tetrakis (trifluorophosphine)platinum, (trimethyl)methyl cyclopentadienylplatinum (IV), (trimethyl)methylcyclopentadienylplatinum(IV), pentamethylcyclopentadienyl rhenium tricarbonyl, i-propylcyclopentadienylrhenium tricarbonyl, rhenium carbonyl, carbonyl(pentamethylcyclopentadienyl)rhodium(I), rhodium(III) acetylacetonate, bis(cyclopentadienyl)ruthenium, bis(ethylcyclo pentadienyl)ruthenium(II), bis(penta methylcyclopentadienyl)ruthenium, bis(2,2,6,6-tetramethyl-3,5-heptanedionato)(1,5-cyclooctadiene)ruthenium(II), ruthenium carbonyl, tris(2,2,6,6-tetramethyl-3,5-heptanedionato)ruthenium(III), tris(2,2,6,6-tetramethyl-3,5-heptanedionato) scandium (III), 2,2,6,6-tetramethyl-3,5-heptanedionato silver(I), triethoxyphosphine (trifluoroacetylacetonate)silver(I), triethylphosphine(6,6,7,7,8,8,8-heptafluoro-2,2-dimethyl-3,5-octanedionate)silver(I), trimethylphosphine(hexafluoroacetylacetonato) silver(I), vinyltriethylsilane(hexafluoroacetylacetonato)silver(I), 2,2,6,6-tetramethyl-3,5-heptanedionato thallium(I), thallium(I) ethoxide, thallium(I) hexafluoro acetylacetonate, N,N′-di-t-butyl-2,3-diamidobutanetin(II), N,N′-di-t-butyl-2,3-diamido butanetin(II), tetrakis(dimethylamino)tin(IV), tetrakis(dimethylamino) tin(IV), tetramethyltin, tin(II) acetylacetonate, tin(IV) t-butoxide, tin(II) hexa fluoroacetylacetonate, cyclopentadienyl(cycloheptatrienyl)titanium(II), tetrakis (diethyl amino)titanium(IV), tetrakis(dimethylamino)titanium(IV), tetrakis(dimethylamino) titanium(IV), titanium(IV) n-butoxide, titanium(IV) t-butoxide, titanium(IV) ethoxide, titanium(IV) i-propoxide, (trimethyl)pentamethyl cyclopentadienyltitanium(IV), tris(2,2,6,6-tetramethyl-3,5-heptanedionato)titanium(III), mesitylene tungsten tricarbonyl, tungsten carbonyl, bis(cyclopentadienyl)vanadium, cyclopentadienyl vanadium tetracarbonyl, vanadium(III) acetylacetonate, vanadium(V) trichloride oxide, vanadium(V) tri-i-propoxy oxide, tris[N,N-bis(trimethylsilyl)amide] yttrium(III), tris(butylcyclopentadienyl)yttrium, tris(cyclopentadienyl)yttrium, tris(methylcyclo pentadienyl)yttrium, tris(n-propylcyclopentadienyl)yttrium, tris(2,2,6,6-tetramethyl-3,5-heptanedionato)yttrium(III), yttrium(III) hexafluoroacetylacetonate, bis(2,2,6,6-tetra methyl-3,5-heptanedionato)zinc, diethylzinc, dimethylzinc, bis(cyclopentadienyl) dimethylzirconium, dimethylbis(t-butylcyclopentadienyl) zirconium, tetrakis(diethyl amino)zirconium, tetrakis(dimethylamino)zirconium, tetrakis(ethylmethylamino) zirconium, tetrakis(2,2,6,6-tetramethyl-3,5-heptanedionato)zirconium(IV), zirconium (IV) t-butoxide, zirconium(IV) ethoxide and zirconium(IV) hexafluoro acetylacetonate.

Any of the above listed metal sources or precursors may be equivalently used with different metal atoms other than the specifically listed. For example, where zirconium(IV) hexafluoro acetylacetonate is provided herein, as an example of a metal source, in a similar fashion a different metal may be used as an hexafluoro acetylacetonate or acetylacetonate complex.

In some embodiments, the metal source or metal precursor is a metal halide.

In other embodiments, the metal source or metal precursor is of Ti, the material being selected from bis(tert-butylcyclopentadienyl)titanium(IV) dichloride; bis(diethylamido) bis(dimethyl amido)titanium(IV); tetrakis(diethylamido)titanium(IV); tetrakis (dimethylamido) titanium(IV); tetrakis(ethylmethylamido)titanium(IV); titanium(IV) diisopropoxidebis (2,2,6,6-tetramethyl-3,5-heptanedionate); titanium(IV) isopropoxide; and titanium tetrachloride.

In some embodiments, the metal source or metal precursor is a metal oxide.

In some embodiments, the metal oxide is as selected above.

In some embodiments, the metal oxide is selected from metal oxides used in super capacitors and batteries. In some embodiments, the metal oxide is selected from RuO₂, IrO₂, V₂O₅, Fe₃O₄, MnO₂, NiO, TiO₂, Co₃O₄ and NiCo₂O₄.

In some embodiments, the metal source is selected from TiCl₄, trimethylaluminum (TMA) and Zn salts or complexes.

The deposition method may also require use of other material precursors such as hydroxide precursors or an oxygen source, and alcohol precursor, etc.

The at least one hydroxide precursor or oxygen sources is any material which upon interaction with the metal atom yields metal atoms that are associated or bonded to one or more oxide or hydroxide groups. Non-limiting examples include water, ozone, organic acid (carboxylic acids) or other forms. The at least one organic alcohol is selected from organic diols, triols, tetraols or any polyhydric alcohol. Non-limiting examples include ethylene glycol, propylene glycol, propylene triol, glycerol, threitol, xylitol, sorbitol and others. In some embodiments, the organic alcohols are selected amongst 1,2-alkyls, 1,3-alkyls, 1,4-alkyls, 1,5-alkyls and higher homologues, as well as triols and tetraol derivatives thereof.

In some embodiments, the metal precursor composition comprises at least one metal source and at least one hydroxyl precursor.

In some embodiments, the metal precursor composition comprises at least one metal source and at least one organic alcohol.

In some embodiments, the metal precursor composition comprises at least one metal source, at least one organic alcohol and at least one hydroxyl precursor.

In some embodiments, the metal precursor composition comprises at least one metal source ethylene glycol and water.

The selection of precursors or materials to be contained in the at least one metal precursor composition depends, inter alia, on the composition of the layer, the method of deposition (e.g., ALD, MLD, etc), the desired functionalities to be included, whether or not the layer formed is to be further modified, the type of polymer, and others. In some embodiments, the composition may further comprise at least one material capable of forming inter or intra layer hydrogen-bonds, at least one material having electron acceptor or electron donor functionalities, at least one material capable of pi stacking or pi-pi interactions, at least one crosslinking material, at least one pH adjusting material, at least one material having hydrophobic or hydrophilic functionalities, at least one material, at least one bifunctional material, and others. In some embodiments, each of the above materials comprises at least one end group having the recited functionality and another end group that is ALD or MLD reactive (e.g., OH group).

The deposition steps may result in wetting regions that are metal oxide regions, metal-organic regions, and/or hybrid organic-inorganic regions. In some embodiments, hybrid wetting regions are formed, said hybrid films comprising metal atoms that are each associated with organic groups and oxides.

In some embodiments, in a deposition method of the invention the precursor temperature is typically between room temperature (23 and 30° C.) and 150° C.

In some embodiments, sample temperature may be 60° C. and 250° C.

In some embodiments, the deposition pressure is typically between 0.1 millibar and 10 millibar.

In some embodiments, the metal precursor dose time is between 100 millisecond and 10 seconds.

In some embodiments, the purge time between doses is typically between 5 second and 300 seconds.

Once a non-continuous wetting film is formed a polymer may be deposited to form the polymer film. Unlike the first step which proceeds in the vapor phase, the second step proceeds in the wet, or in a solution phase.

To form the polymer film a polymer in a flowable form, or a polymer precursor, e.g., a resin or a prepolymer, may be applied onto the non-continuous wetting film and is allowed to cure. The application proceeds in solution. Where the modified carbon-based material, namely the material having been modified with a non-continuous wetting film, is a particulate material or a powder, application may be achievable by adding the powder into a medium comprising polymer/resin/prepolymer and optionally a hardener or any other additive, under conditions permitting association of the polymer/resin/prepolymer with the wetting film. Such conditions include use of a mechanical homogenizer or ultrasonic homogenizer or by other means typically used to make homogeneous mixtures.

Where the carbon-based material is a macrostructure such as a CNT mat, application of a composition or a combination or a mixture of the polymer/resin/prepolymer with optionally a hardener or any other additive may be by any manual or mechanical or automatic application means, including for example brushing, dipping, spraying or by any other means. The composition typically comprises a resin or a prepolymer and at least one hardener or a crosslinking agent. The ratio resin:hardener is between 100:10 to 100:50 (w/w).

Following application of the resin:hardener mixture, the film is allowed to cure under reduced pressure and increased temperature. In some embodiments, curing proceeds at a pressure of between 1000 and 3000 psi. In some embodiments, curing proceeds at a temperature between 50 and 150° C.

In some embodiments, the pressure is between 1000 and 2900, 1000 and 2800, 1000 and 2700, 1000 and 2600, 1000 and 2500, 1000 and 2400, 1000 and 2300, 1000 and 2200 or between 1000 and 2100 psi. In some embodiments, the pressure is between 1500 and 3000, 1800 and 3000, 2000 and 3000, 1500 and 2500, or between 1800 and 2200 psi. In some embodiments, the pressure is 1000, 1100, 1200, 1300, 1400, 1500, 1600, 1700, 1800, 1900, 2000, 2100, 2200, 2300, 2400, 2500, 2600, 2700, 2800, 2900 or 3000 psi.

In some embodiments, the curing temperature is between 50 and 150, 50 and 140, 50 and 130, 50 and 120, 50 and 110, 50 and 100, 50 and 90, 50 and 80, 60 and 150, 60 and 120, 60 and 110, or between 60 and 90° C.

In some embodiments, prior to curing, the polymer/resin/prepolymer film is allowed to dry at room temperature (between 23 and 35° C.).

Thus, a composite of the invention is manufactured by a process comprising
vapor deposition of a metal-based wetting material on a surface of a carbon-based material such as CNT or CNT microstructures, e.g., CNT mat, wherein the deposition is by ALD, MLD or any of the other deposition methods disclosed herein, to form a non-continuous wetting film on said surface;
wet deposition of a composition comprising a polymer or a polymer resin or a prepolymer and optionally a hardener on the non-continuous wetting film to form a film of said composition; and
curing the deposited film, e.g., to cause association of the polymer with the non-continuous wetting film and exposed regions of the carbon-based material; to thereby obtain the composite.

In some embodiments, the process comprises obtaining the carbon-based material.

In some embodiments, the process comprises treating the carbon-based material in a reactor under ALD or MLD conditions.

In some embodiments, the non-continuous wetting film is a metalcone film.

In some embodiments, the carbon-based material is a CNT macrostructure, e.g., a CNT mat.

In some embodiments, the non-continuous wetting film is formed in advance or at a time period substantially preceding the deposition of the polymer.

Thus, a process is provided which comprises wet deposition of a composition comprising a polymer or a polymer resin or a prepolymer and optionally a hardener on a non-continuous wetting film provided on a carbon-based material to form a film of said composition; and curing the deposited film; to thereby obtain the composite.

In some embodiments, the process comprises obtaining the carbon-based material.

In some embodiments, the process comprises vapor deposition of a metal-based wetting material on a surface of the carbon-based material such as CNT or CNT macrostructures, e.g., CNT mat, wherein the deposition is by ALD, MLD or any of the other deposition methods disclosed herein, to form a non-continuous wetting film on said surface.

In some embodiments, the process comprises treating the carbon-based material in a reactor under ALD or MLD conditions.

In some embodiments, the non-continuous wetting film is a metalcone film.

In some embodiments, the carbon-based material is a CNT macrostructure, e.g., a CNT mat.

The hardener used in the curing of the polymer may be any material or a mixture of materials used to increase resilience of the polymer once it sets, or to cause curing of the polymer components. According to processes herein, the hardener can be either a reactant or a catalyst or an accelerator or as a crosslinking agent. Where an epoxy resin is used, the hardener is selected to ensure the epoxy mixture meets the requirements of the application. Typically, the hardener may be selected amongst anhydride-based, amine-based, polyamide, aliphatic and cycloaliphatic hardeners. Non-limiting examples include methylene dianiline, diethyl aminopropylamine, diethylenetriamine, ethylenediamine, m-phenylenediamine, tris-(dimethylaminomethyl) phenol, triethylenetetramine, dicyandiamide, isopropyl metaphenylenediamine, hexahydrophthalic anhydride, 4,4-methylen-bis-(2-chloranilin), and others.

In some embodiments, the hardener is an amine based or a diamine material, as selected above.

### BRIEF DESCRIPTION OF THE DRAWINGS

To better understand the subject matter that is disclosed herein and to exemplify how it may be carried out in practice, embodiments will now be described, by way of non-limiting example only, with reference to the accompanying drawings, in which:

FIG. 1 shows a CNT mat (31 gm⁻²) used in accordance with aspects and embodiments of the invention.

FIG. 2 illustrates an exemplary preparation method of CNT-epoxy composite according to certain embodiments of the invention. (a) Preparation of resin/hardener mixture—resin:hardener weight ratio is 38:100 (w:w). (b) Placing CNT mat on aluminum plate holder covered with non-stick paper and brushing with the resin-hardener mixture (repeated twice). Excess is removed with a silicone wiper. (c) RT curing in a vacuum bag and pump it for 24 h. (d) Post curing 80° C. for 5 h.

FIG. 3 presents a typical stress-strain curve. The slope of the linear region (part A) represents the stiffness of the material. Yield point is the stress beyond which a material becomes plastic (area B). Ultimate strength is the maximum stress that the material can withstand under external force (part C). Fracture point is the point of strain where the material physically separates.

### DETAILED DESCRIPTION OF EMBODIMENTS

### Materials and Methods

### CNT Mat Substrate

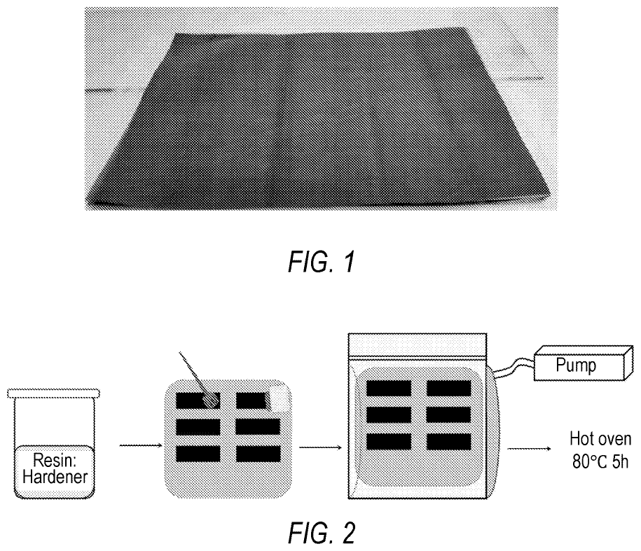

CNT mats were obtained from “Tortech nano fibers”, A4 sheet size. The CNT mats were synthesized by floating catalyst chemical vapor deposition (FCCVD) reaction. The feedstock contains carbon source, methane, ethanol, ferrocene and thiophene. The ferrocene acts as the catalyst source for this reaction. Pyrolysis under reducing environment results in iron nanoparticles with Sulphur shell. Fullerene caps form on the surface of the nanoparticles which then evolve into individual CNTs. As CNTs become longer and bind into a network of CNT bundles induced by van der walls interactions. This continuous cylindrical network form is spun around the drum and drawn into a non-woven mat (shown in FIG. 1). CNT mats can be obtained with thickness ranging between 10 s-100 s of microns depending on the drum collection time with the corresponding surface densities of ˜2-50 gm⁻². The CNT mats contain about 10% w/w of catalyst residues (Fe and S) originating from the synthesis.

Ultra-high purity Ar gas is used as a carrier gas in a hot wall reactor and purge between reactant exposures. The control of the precursors dosing is done by computer controlled pneumatic valves at a steady pressure of 1.5×10⁻¹ mbar maintained during the process. Whole CNT mats samples (60×90 mm) are prepared by loading the samples to the reactor allowing the temperature to stabilize for 30 minutes and dosing the reactant precursors into Ar carrier gas. The silane precursors are kept at 80° C. and the sample reactor temperature is set to 171° C. with actual sample tray temperature 153° C.

### Wet Lay-Up Technique

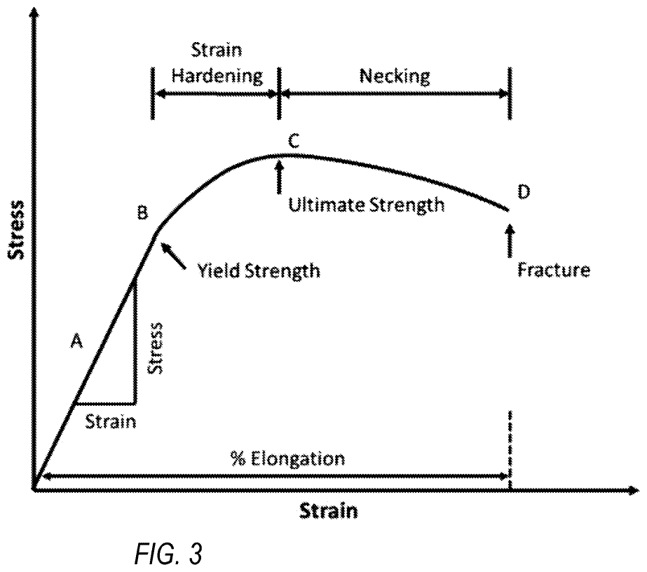

Epoxy system Araldite LY 5052 resin Aradur 5052 hardener is used to form the CNT mat-epoxy composites of the invention. The resin density is 1.17 g/cm³ and the hardener density is hardener Density 0.95 g/cm³. This epoxy system is commonly used in aircraft components with relatively low mixture viscosity of ˜0.500-700 cP (at 25° C.) and molar mass is less than 700 gmol⁻¹. Preparation of CNT mat-epoxy composite is performed as described below (FIG. 2):
(I) A mixture of resin:hardener was prepared in a weight ratio of 100:38 (w:w).
(II) Samples are placed on aluminum plate coated with non-stick teflon film and were loaded with the resin:hardener mixture layer and applied using a brush to ensure full and uniform impregnation of the mixture onto the mat excess mixture is removed using a silicone spatula. This step is repeated twice.
(III) Samples were loaded to a vacuum bag connected to a pump for 24 hours curing at room temperature under external pressure of 2000 psi.
(IV) Samples were cured for 5 hours at 80° C. under external pressure of 2000 psi.

For all experiments, both M/ALD treated and un-treated composite samples are prepared for comparison. Epoxy type Araldite LY 5052 Aradur 5052 compose of epoxy resin phenol novolac (EPN) and Isophorone diamine (IPDA) as the hardener.

### Contact Angle Measurement

Contact angle (CA) is defined as the angle formed by a liquid at the three-phase boundary where a liquid-vapor interface meets a solid surface. CA is often used to quantify the surface wettability of a solid surface by liquid.

CA measurements were performed using ultra-pure water (>18MΩ, ELGA purification system) and epoxy Araldite LY5052 Aradur 5052 mixture that is used for the composite formation using Attension goniometer equipped with “Theta Lite” software. The measurement is performed three times for each sample to achieved repeatability.

### Tensile Testing

Tensile testing is applied to CNT mats and their epoxy composites for mechanical testing. Material properties measured via a tension test include ultimate strength, elongation, young's modulus and toughness. Material properties are expressed by stress, force per unit area (σ) and strain, percent change in length (ε). To obtain the stress, the force is divided by the sample cross sectional area (σ=F/A). Strain is obtained by dividing the change in length by the initial length of the sample (ε=ΔL/L). It is common to plot the stress as a function of the strain, referred to as ‘Stress-Strain Curve’ (FIG. 3). Each material has a unique curve, but for most materials, the initial curve is a straight line reflecting the linear relationship between the stress and strain. This is called the ‘Elastic’ range which can describe by Hooke's Law (F=−kΔL), where the ratio of stress to strain is constant:

$$\frac{F}{A} = E \frac{Δ L}{L} \qquad ( Eq . 5 )$$

The slope of the stress strain curve at the linear region is equivalent to young's modulus of elasticity (E). Young's modulus is a measure of the stiffness of the material and defines the ability of a material to withstand changes in length when under longitude tension. This linear region represents basic linear elastic stress-strain relationship assuming there is no plastic deformation. Toughness is a mechanical property which defines the ability of a material to absorb energy and plastically deform without fracturing. Toughness is quantified as the area under the stress-strain curve. Young's modulus, toughness, ultimate strength and Ultimate strain.

Elastic Hysteresis is the difference between the strain energy required to generate a given stress in a material, and the material's elastic energy at that stress. This energy is dissipated as internal friction (heat) in a material during one cycle of testing (loading and unloading). It is clear that modified CNT mat shows different behavior in the plastic region. The untreated CNT mat reveals the maximal strain of 3.2% while for modified CNT mat, the strain values are 7.7% and 4.5% for M/ALD (DMASi) and M/ALD (MMASi) treatments, respectively. This observation demonstrates that the M/ALD treatment allows the CNT mat-epoxy composite to absorb more energy before rupture and to withstand under higher stress values. It also can be seen that the M/ALD (DMASi) treatment show better improvement than M/ALD (MMASi) treatment, as shown in the mechanical property analysis above.

1.-87. (canceled)

88. A composite in a form of a 3D object of a carbon-based material, the object being associated with a continuous film of at least one polymeric material on at least a region of its surface, the film being associated with the 3D object via a plurality of regions of a metal-based wetting material selected to tune wettability of the carbon-based material, thereby permitting association of the polymeric material with both the carbon-based material forming the object and the metal-based wetting material.

89. The composite according to claim 88, wherein the thickness of the wetting film is between 1 and 100 nm.

90. The composite according to claim 88, wherein the thickness of the regions of the non-continuous wetting film and the polymeric film, combined, ranging from 10 nm to 5 mm.

91. The composite according to claim 88, wherein the carbon-based material is a carbon allotrope.

92. The composite according to claim 88, wherein the carbon-based material is selected from graphite, carbon fibers, carbon black powder, amorphous carbon powder, carbon nanofoam, glassy carbon, graphene and graphene flakes, graphene oxide, reduced graphene oxide, carbon nanofibers, carbon nanotubes (CNTs), fullerenes (buckyballs), diamond powder, diamond nanoparticles and diamond coating.

93. The composite according to claim 92, wherein the carbon-based material is graphene or a graphene-based structure, optionally selected from graphene flakes, graphene nanosheets, graphene nanoribbons, and graphene nanoparticles.

94. The composite according to claim 92, wherein the carbon-based material is CNT.

95. The composite according to claim 94, wherein the CNT is in a form of a collection of CNTs or as a CNT assembly.

96. The composite according to claim 95, wherein the CNT assembly is selected from a CNT bundle or a CNT web.

97. The composite according to claim 88, wherein the non-continuous metal-based wetting film is free of surfactants.

98. The composite according to claim 88, wherein the metal-based wetting material is an inorganic material, organic material or a hybrid material comprising.

99. The composite material according to claim 98, wherein the metal-based wetting material comprises a plurality of metal atoms in-layer associated to each other, directly or via bridging atoms or organic ligands, wherein the metal atoms are further associated with one or more surface exposed functionalities which are selected to endow hydrophilicity to the wetting film.

100. The composite according to claim 99, wherein the surface exposed functionalities are hydroxide functionalities, oxide functionalities, alkoxide functionalities, amine functionalities, or benzyl functionalities.

101. The composite according to claim 88, wherein the carbon-based material is or comprises CNT and the non-continuous wetting film is or comprises a metalcone.

102. The composite according to claim 88, the composite comprising a carbon-based material being or comprising CNT coated with a non-continuous wetting film of a metal-based wetting material, the non-continuous wetting film being associated with a film of an epoxy material (polyepoxide).

103. A composite material comprising a CNT mat having a non-continuous wetting film associating a film of epoxy (polyepoxide).

104. A CNT mat having an epoxy film on at least a region of its surface, the film being associated with the CNT mat via a non-continuous wetting film comprising a plurality of spaced-apart regions of a metal-based wetting material that are non-covalently associated with CNTs in said CNT mat.

105. A process for manufacturing a composite material of at least one carbon-based material and a polymer, the process comprising:
vapor deposition of a non-continuous metal-based wetting film; and
wet or melt deposition of a polymer film, optionally via deposition of a polymer melt or deposition of a polymerizable polymer precursor.

106. The process according to claim 105, wherein the non-continuous metal-based wetting film is provided directly on the carbon-based material by vapor phase deposition being one or a combination of atomic layer deposition (ALD), molecular layer deposition (MLD), combined ALD/MLD, spatial ALD, and tandem catalyst ALD/MLD.

107. A process for forming a composite according to claim 88, the process comprising:
vapor deposition of a metal-based wetting material on a surface of a carbon-based material, wherein the deposition is by ALD, MLD or a deposition method comprising same, to form a non-continuous wetting film on said surface;
wet deposition of a composition comprising a polymer or a polymer resin or a prepolymer or deposition of a polymer melt and optionally a hardener on the non-continuous wetting film to form a film of said composition or polymer; and
curing the deposited film to thereby permit association of the polymer with the non-continuous wetting film and with exposed regions of the carbon-based material, to thereby obtain the composite.
